(19) United States
(12) Patent Application Publication
(10) Pub. No.: US 2012/0081614 A1
(43) Pub. Date: Apr. 5, 2012

(54) LIGHT-EMITTING MODULE, ILLUMINATION DEVICE, DISPLAY DEVICE, AND TELEVISION RECEIVER

(75) Inventor: Kaori Yamamoto, Osaka-shi (JP)

(73) Assignee: SHARP KABUSHIKI KAISHA, Osaka-shi, Osaka (JP)

(21) Appl. No.: 13/376,395

(22) PCT Filed: Mar. 15, 2010
(86) PCT No.: PCT/JP2010/054306

§ 371 Date: Dec. 6, 2011

(30) Foreign Application Priority Data
Jun. 15, 2009 (JP) 2009-141919

(51) Int. Cl. H01L 33/60; H04N 5/44

(52) U.S. Cl. 348/725; 257/98; 257/91; 257/E33.06; 348/E05.096

(57) ABSTRACT

An LED module (MJ) includes an LED (22), a mounting substrate (21) for mounting the LED (22), a lens (24) in which light from the LED (22) is output from a lens surface (24S), and a built-in reflective sheet (11) interposed between a back surface (24B) of the lens surface (24S) and the mounting substrate (21), and provided with a built-in reflective surface (11U) facing the back surface (24B) of the lens surface (24S).

### TECHNICAL FIELD

The present invention relates to a light-emitting module including a light source such as a light-emitting element, an illumination device using the light-emitting module, a display device in which the illumination device is installed, and a television receiver in which the display device is installed.

### BACKGROUND ART

A backlight unit (illumination device) for supplying light to the liquid crystal display panel is usually installed in liquid crystal display devices (display devices) in which a non-light-emitting liquid crystal display panel (display panel) is installed. There are various types of light sources for a backlight unit. For example, in the case of the backlight unit shown in Patent Literature 1, the light source is an LED (light-emitting diode).

Moreover, lenses 124 that allow permeation of light from LEDs 122 mounted on a mounting substrate 121 are attached in the backlight unit described in Patent Literature 1, as shown in FIG. 18 (a module including at least an LED 122 and a lens 124 is referred to as a light-emitting module mj). In such a case, light is caused to converge by the lenses 124 and is propagated along a comparatively vertical direction, as shown in the image in FIG. 19. Illuminance at a direct viewing angle of backlight light from the backlight unit is thereby improved.

### LIST OF CITATIONS

### Patent Literature

Patent Literature 1: JP-A 2008-41546

### SUMMARY OF INVENTION

### Technical Problem

However, when illuminance from the front surface of two LEDs 122 is photographed by a photo camera, an image such as that shown in FIG. 20 is obtained (in producing the photo, a diffuser is interposed between the photo camera and the lenses 124, and the diffuser is photographed).

In the image, the circular image having dashed/dotted lines represents light that passed through the lenses 124. The image demarcated by the dotted circle is included inside the circular image having dashed/dotted lines.

These circular lines show the boundaries of the illuminance range, which is the contrast. The image in FIG. 20 therefore includes a plurality of ranges corresponding to the illuminance. Here, ar1 is an area encircled by only the dotted line, ar2 is an area encircled by the dotted line and the dotted/dashed line, and ar3 is another area not encircled by the dotted or dashed lines. Assuming that the illuminance (lumen) of areas ar1, ar2, ar3 is set to lm1, lm2, lm3, the relationship among them will be lm1>lm2>lm3 (the relations lm1>68%, 64%<lm2≦68%, and 50%<lm3≦64% will be obtained if lm1, lm2, and lm3 are normalized to maximum illuminance).

A bright illuminance range is preferably made as large as possible so that irregularities in the quantity of light do not occur in the light (backlight light) from the backlight unit. It can then be concluded that the area ar1 of the highest illuminance lm1 in the image in FIG. 20 is preferably the largest possible (however, this is merely one of the indicators for reducing irregularities in the quantity of light, and there are naturally other indicators).

However, the area ar1 is simply one part in the entire illuminance range and is comparatively small, as is apparent from the image in FIG. 20. In other words, even though the illuminance at a direct viewing angle improves in a backlight unit using light that passes through the hemispherical lenses 124, irregularities in the quantity of light cannot be prevented.

The present invention was perfected in order to solve the aforementioned problems. An object of the present invention is to provide a light-emitting module and the like capable of ensuring an illuminance range having a comparatively high illuminance in order to suppress irregularities in the quantity of light.

### Solution to Problem

A light-emitting module comprises a light-emitting element, a mounting substrate for mounting the light-emitting element, a lens in which light from the light-emitting element is output from a lens surface, and a first reflective sheet interposed between a back surface of the lens surface and the mounting substrate, and provided with a reflective surface facing the back surface of the lens surface.

In such a case, the light reflected by the back surface of the lens is reflected by the reflective surface of the first reflective sheet and transmitted so as to return to the back surface of the lens. Therefore, situations are prevented in which the light reflected by the back surface of the lens is absorbed by the mounting substrate, or is reflected by the mounting substrate and fails to become incident on the back surface of the lens. In other words, the light from the light-emitting element is output via the lens without loss. As a result, there is an increase in the illuminance of the entire illuminance range based on the light-emitting module.

In addition, the reflective surface of the first reflective sheet is preferably a Lambert scattering surface. In cases in which Lambert scattering occurs on the reflective surface, the scattered light is transmitted in various directions. It is therefore less likely that light transmitted in a particular direction is transmitted outside of the back surface of the lens, as is the case with, for example, Gaussian scattering, and substantially all of the light transmitted in various directions by Lambert scattering is transmitted so as to return to the back surface of the lens. The light from the light-emitting element is therefore output via the lens without loss.

In addition, the back surface of the lens surface is preferably a Lambert scattering surface. In such a case, the light incident on the inside of the lens is transmitted in various directions. Therefore, irregularities in the quantity of light rarely occur in the light from the lens.

The Lambert scattering surface is preferably a textured surface or a coating surface coated with scattering particles. The degree of roughness on the Lambert scattering surface may be varied, but in terms of enhancing light-scattering properties, the surface roughness (Ra) is, for example, preferably 400 nm or greater.

In addition, the lens is preferably a diffusion lens. In such a case, irregularities in the quantity of light rarely occur in the light from the light-emitting module because the light permeating the diffusion lens is diffused.

In an illumination device comprising the aforementioned light-emitting module, the illuminance of the entire illuminance range based on the illuminance device is increased because the light from the light-emitting element in the light-emitting module is output from the lens surface without loss.

In such an illumination device, a second reflective sheet is preferably disposed between the lenses in a pair, and the reflectance of the second reflective sheet is preferably 97% or greater. In such a case, a dark section corresponding to the space between the lenses rarely occurs in the light from the light-emitting module, and irregularities in the quantity of light rarely occur in the light from the illumination device.

Moreover, a display device comprising the illumination device and a display panel (a liquid crystal display panel, for example) for receiving light from the illumination device provides a high-quality image obtained due to the increased illuminance in the illumination device and devoid of irregularities in the quantity of light (a television receiver can be given as an example of a device in which such a display device is installed).

### Advantageous Effects of the Invention

According to the light-emitting module of the present invention, light from a light-emitting element is output via a lens without loss by interposing a reflective sheet between a lens and a mounting substrate. As a result, the illuminance of the entire illuminance range based on the light-emitting module is increased.

### BRIEF DESCRIPTION OF DRAWINGS

FIG. 1 is an exploded perspective view of an LED module;

FIG. 2 is an exploded cross-sectional view of an LED module (the cross-sectional direction is the direction of the arrowed line A-A′ in FIG. 1);

FIG. 3 is an exploded plan view of an LED module;

FIG. 4 is a side view of an LED module;

FIG. 5 is an image showing light that is output from the LED module in FIG. 1;

FIG. 6 is a schematic perspective view of a simulation device;

FIG. 7 is an image showing the illuminance distribution of light (Gaussian scattered light) that is output via two lenses;

FIG. 8 is an explanatory view describing Gaussian scattering;

FIG. 9 is an explanatory view describing Lambert scattering;

FIG. 10 is a graph obtained by measuring light that underwent Lambert scattering;

FIG. 11 is an optical path diagram showing light reflected by a built-in reflective sheet;

FIG. 12 is an image showing the illuminance distribution of light (Lambert scattered light) that is output via two lenses;

FIG. 13 is an optical path diagram showing scattering at the back surface of a lens;

FIG. 14 is an explanatory view comparing lens position and brightness;

FIG. 15 is an exploded plan view of an LED module;

FIG. 16 is an exploded perspective view of a liquid crystal display device;

FIG. 17 is an exploded perspective view of a liquid crystal television in which a liquid crystal display device is installed;

FIG. 18 is an exploded perspective view of a conventional backlight unit;

FIG. 19 is an image showing light that is output from a conventional LED module; and

FIG. 20 is an image showing the illuminance distribution of light that is output via two lenses in the LED module shown in FIG. 19.

### DESCRIPTION OF EMBODIMENTS

### First Embodiment

An embodiment is described below with reference to the drawings. Cross-hatching and component labels will sometimes be omitted for convenience, in which case other drawings will be referenced.

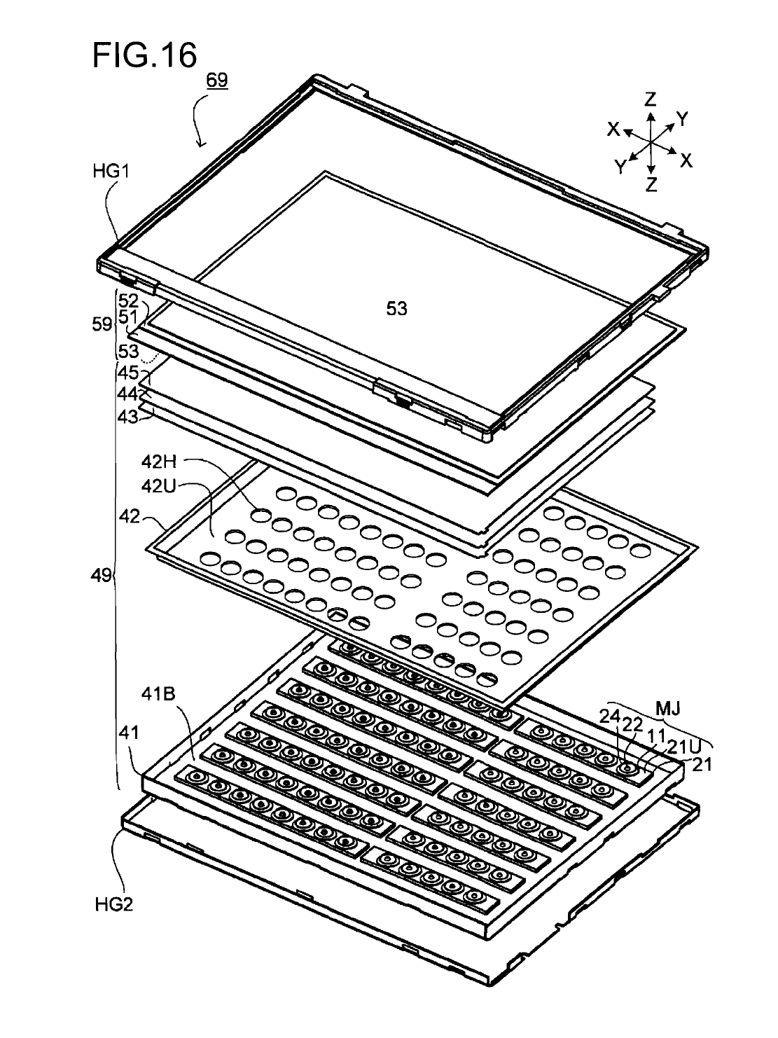

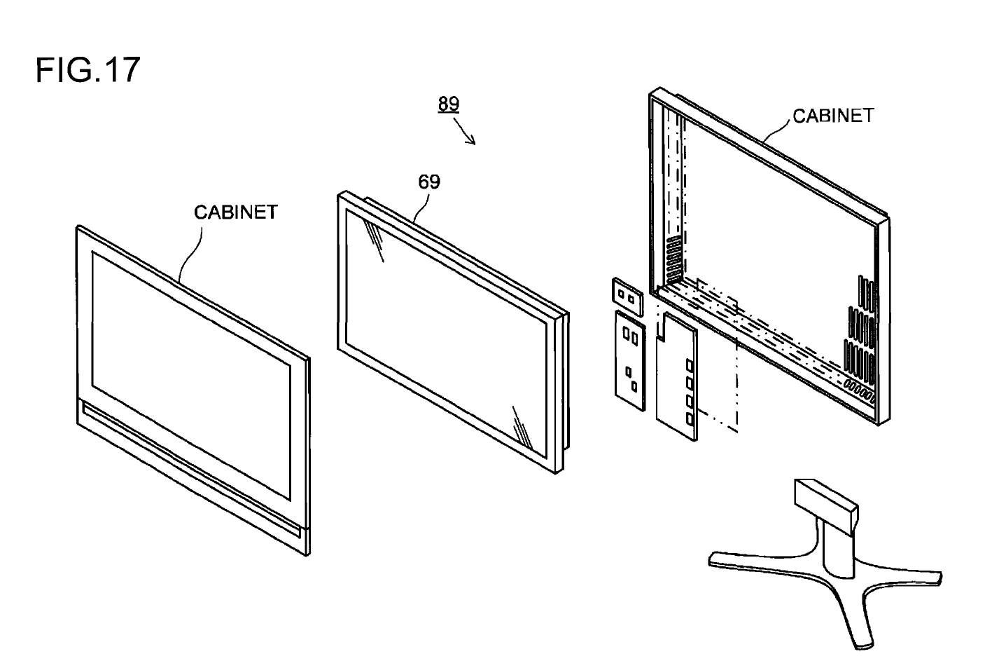

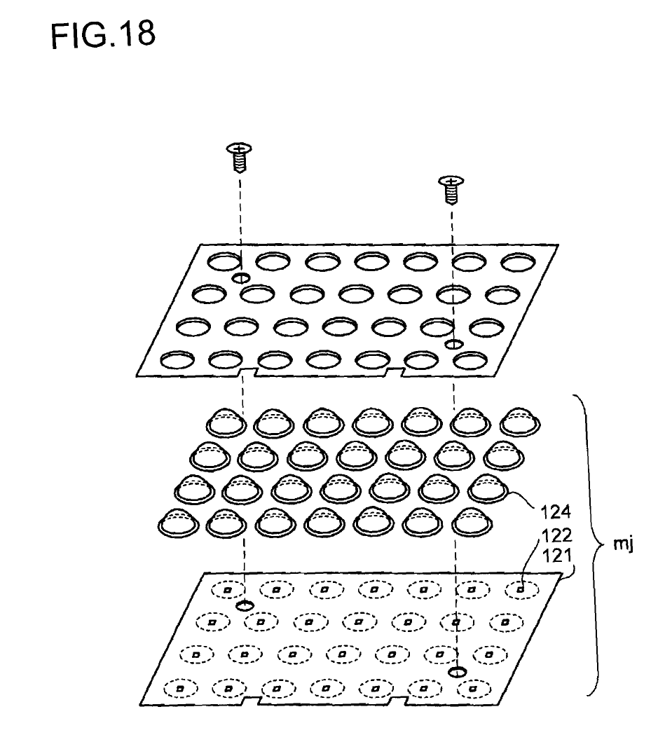

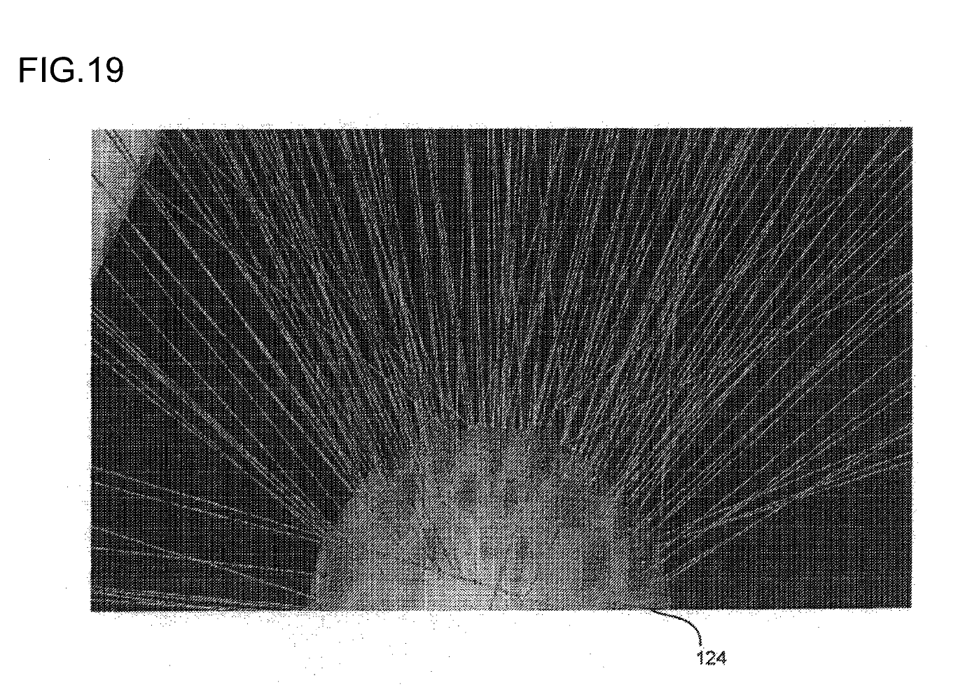

FIG. 17 shows a liquid crystal television 89 in which a liquid crystal display device (display device) 69 is installed. Such a liquid crystal television 89 receives a television broadcast signal to project an image, and is therefore referred to as a television receiver. FIG. 16 is an exploded perspective view showing the liquid crystal display device (display device) 69. The liquid crystal display device 69 includes a liquid crystal display panel (display panel) 59, a backlight unit (illumination device) 49 for supplying light to the liquid crystal display panel 59, and a housing HG (front housing HG1 and back housing HG2) interposed therein, as shown in FIG. 16.

In the liquid crystal display panel 59, an active matrix substrate 51 including a TFT (thin film transistor) or other switching element, and an opposing substrate 52 facing the active matrix substrate 51 are bonded to each other by a sealant (not shown). Liquid crystal (not shown) is injected in the gap between the two substrates 51, 52.

A polarizing film 53 is attached to the light-receiving surface of the active matrix substrate 51 and the output side of the opposing substrate 52. A liquid crystal display panel 59 such as described above uses the change in permeability caused by the inclination of the liquid crystal molecules to display an image.

The backlight unit 49 positioned directly below the liquid crystal display panel 59 will be described next. The backlight unit 49 includes LED modules (light-emitting modules) MJ, a backlight chassis 41, a large reflective sheet 42, a diffuser 43, a prism sheet 44, and a microlens sheet 45.

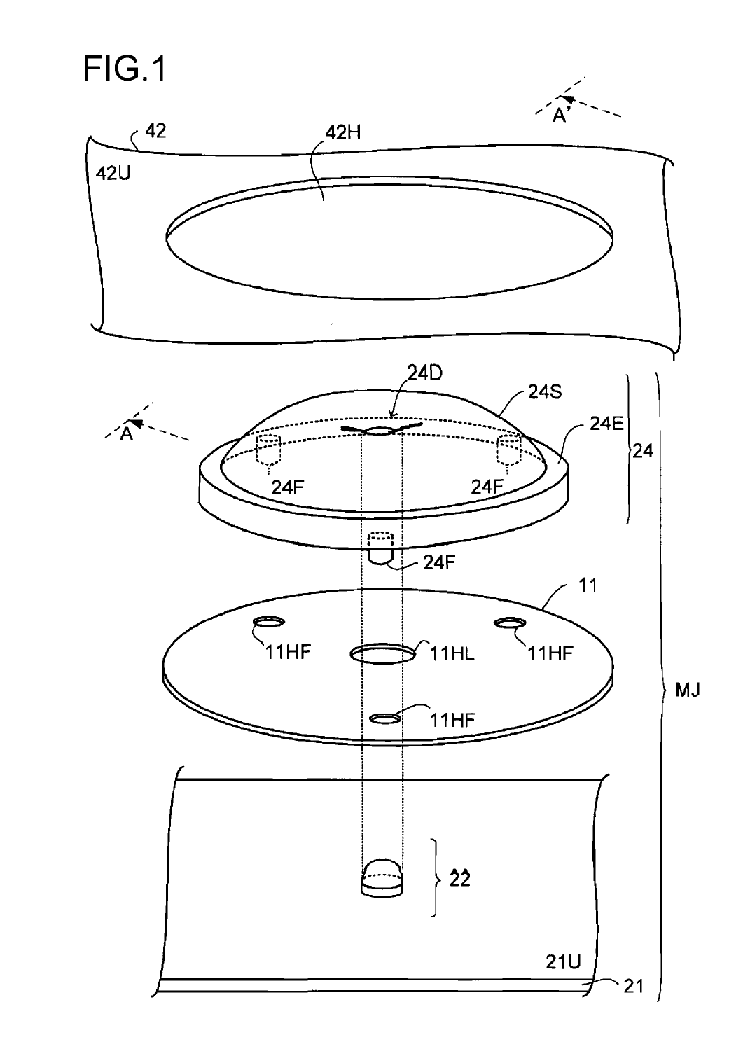

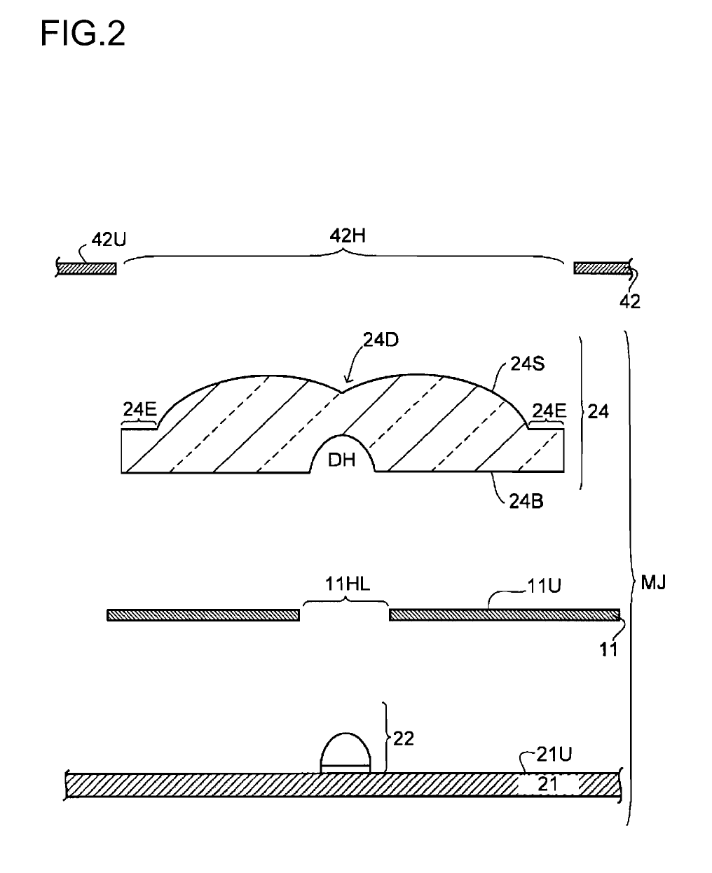

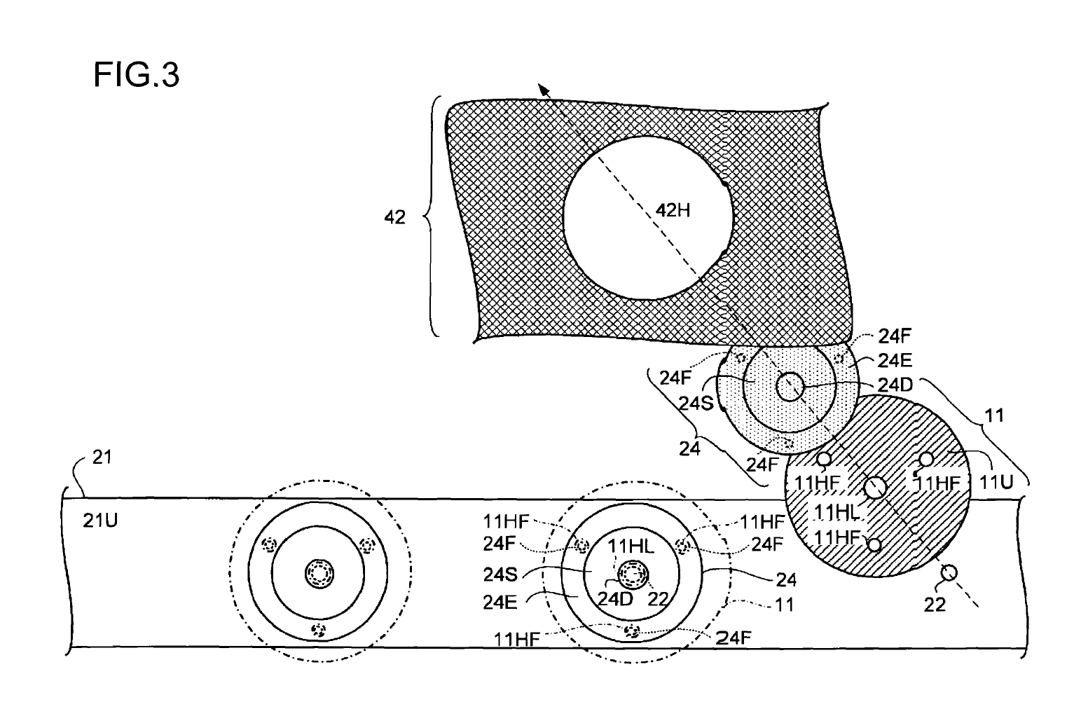

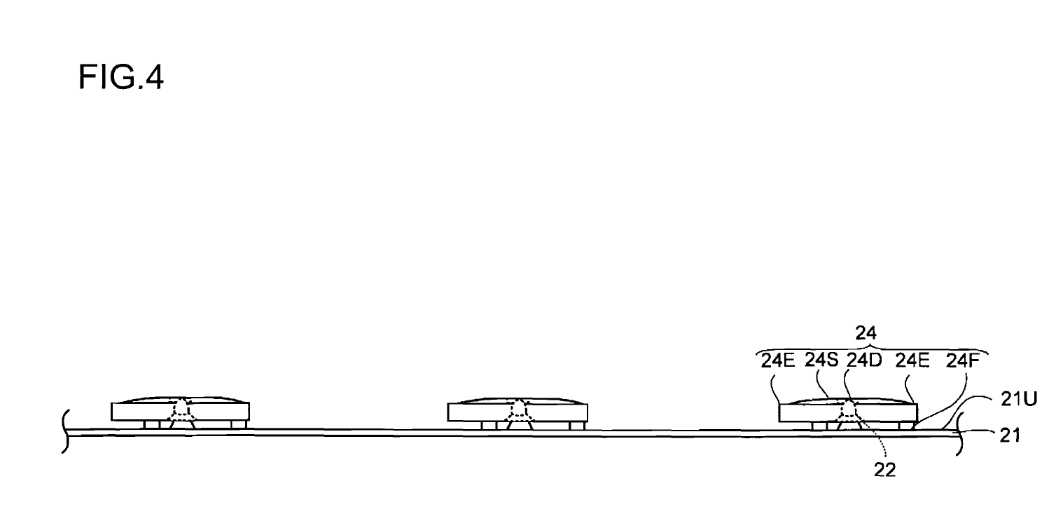

The LED modules MJ are shown in FIGS. 1 to 4 as well as in FIG. 16. FIG. 1 is a partial perspective view of FIG. 16, and FIG. 2 is a cross-sectional view along arrowed line A-A′ in FIG. 1. FIG. 3 is an exploded plan view illustrating various members shown in FIG. 1, and FIG. 4 is a side view of FIG. 3. In FIG. 3, the below-described built-in reflective sheet 11 is sometimes illustrated by a dotted/dashed line for convenience, and members positioned at the top of the dashed arrow are placed over members at the base of the dashed arrow. In FIG. 4, the below-described built-in reflective sheet 11 and the large reflective sheet 42 are omitted for convenience.

The LED modules MJ include a mounting substrate 21, an LED (light-emitting diode) 22, a lens 24, and a built-in reflective sheet (first reflective sheet) 11, as shown in these drawings.

The mounting substrate 21 is a tabular, rectangular substrate, and a plurality of electrodes (not shown) is lined up on a mounting surface 21U. The LED 22, which is the light-emitting element, is attached to the electrodes. A resist film (not shown) serving as a protective film is formed on the mounting surface 21U in the mounting substrate 21. The resist film is not particularly limited, but is preferably white and has reflective properties. This is because any light that is incident on the resist film tends to be reflected by the resist film and directed to the outside, resolving the cause of irregularities in the quantity of light, such as absorption of light by the mounting substrate 21.

The LED 22 is a light source and is caused to emit light by the passage of electric current via the electrodes of the mounting substrate 21. There are many types of LEDs 22, and an LED 22 such as the following can be given as an example. This LED 22 may, for example, include an LED chip (light-emitting chip) that emits blue light, and a phosphor for receiving the light from the LED chip and producing yellow light as a fluorescent emission (the number of LED chips is not particularly limited). Such an LED 22 generates white light using the blue light emitted by the LED chip, and the light produced as a fluorescent emission.

The phosphor built into the LED 22 is not limited to a phosphor for producing yellow light as a fluorescent emission. The LED 22 may, for example, include an LED chip that emits blue light, and a phosphor for receiving the light from the LED chip and producing green and red light as a fluorescent emission, and may generate white light using blue light from the LED chip and light (green and red light) produced as a fluorescent emission.

The LED chip built into the LED 22 is not limited to one that emits blue light. The LED 22 may, for example, include a red LED chip that emits red light, a blue LED chip that emits blue light, and a phosphor for receiving the light from the blue LED chip and producing green light as a fluorescent emission. This is because such an LED 22 can generate white light using red light from the red LED chip, blue light from the blue LED chip, and green light produced as a fluorescent emission.

A completely phosphor-free LED 22 may also be employed. The LED 22 may, for example, include a red LED chip that emits red light, a green LED chip that emits green light, and a blue LED chip that emits blue light, and may generate white light using the light from all of the LED chips.

Comparatively short mounting substrates 21 on which five LEDs 22 are mounted in a row on one mounting substrate 21, and comparatively long mounting substrates 21 on which eight LEDs 22 are mounted in a row on one mounting substrate 21 are installed in the backlight unit 49 shown in FIG. 16.

In particular, the two types of mounting substrates 21 are lined up so that a row having five LEDs 22 and a row having eight LEDs 22 form a row having thirteen LEDs 22, and the two types of mounting substrates 21 are further lined up in a direction intersecting (orthogonal to or the like) the direction in which the thirteen LEDs 22 are lined up. The LEDs 22 are thereby disposed in a matrix and generate planar light (for convenience, the X direction is the direction in which different types of mounting substrates 21 are lined up, the Y direction is the direction in which the same types of mounting substrates 21 are lined up, and the Z direction is the direction that intersects the X and Y directions).

The thirteen LEDs 22 lined up in the X direction are electrically connected in series, and these thirteen serially attached LEDs 22 are electrically connected in parallel to another thirteen serially connected LEDs 22 that are adjacent to each other along the Y direction. The LEDs 22 lined up in a matrix are driven in parallel.

The built-in reflective sheet 11 is a sheet having a reflective surface (built-in reflective surface) 11U, and the rear surface of the reflective surface 11U is attached facing the mounting surface 21U of the mounting substrate 21 (the built-in reflective surface 11U will be described in detail below). Light from the LED 22 is not obstructed because the built-in reflective sheet 11 includes LED apertures 11HL for exposing the LED 22 in the built-in reflective surface 11U.

The built-in reflective sheet 11 includes leg apertures 11HF for allowing the below-described legs 24F of the lens 24 to pass through so as not to obstruct the connection between the mounting substrate 21 and the lens 24 on the sheet. In other words, the built-in reflective sheet 11 is covered by the lens 24, and is thereby interposed between the lens 24 and the mounting substrate 21. The built-in reflective sheet 11 prevents the mounting surface 21U of the mounting substrate 21 from being exposed via a through-hole 42H for allowing the lens 24 formed on the large reflective sheet 42 to pass through.

Explained in detail, the large reflective sheet 42 includes the through-hole 42H, which is larger than the outside diameter of the lens 24, in order to expose the lens 24 in a large reflective surface 42U. In cases in which the lens 24 is exposed in the large reflective surface 42U of the large reflective sheet 42, a gap is created between an outside edge 24E of the lens 24 and an inside edge of the through-hole 42H, and there is concern that the mounting surface 21U of the mounting substrate 21 will be exposed via this gap. In view of this, the built-in reflective sheet 11 is a shape that borders the outside edge 24E of the lens 24 (an outer shape that encircles the outside edge 24E), for example, a circle such as the one shown in FIG. 1.

The lens 24 overlaps the built-in reflective surface 11U of the built-in reflective sheet 11, receives light from the LED 22, and allows the light to permeate (be output). Explained in detail, the lens 24 has an accommodating depression DH capable of accommodating the LED 22 on a back surface 24B (light-emitting surface) opposite to a lens surface 24S, as shown in FIG. 2. The lens 24 covers the LED 22 exposed via the built-in reflective sheet 11 while the positions of the accommodating depression DH and the LED 22 are aligned. The LED 22 is then embedded inside of the lens 24, and light from the LED 22 is securely supplied to the inside of the lens 24. The majority of the supplied light is output to the outside via the lens surface 24S.

The lens surface 24S has a recessed hole 24D in which the part of the lens surface 24S that overlaps the accommodating depression DH (specifically, the LED 22) is recessed, as shown, for example, in FIGS. 1 to 4. In such a case, a curved surface divided by the recessed hole 24D as the boundary is created on the lens surface 24S, and less light having a comparatively high optical intensity is allowed to concentrate at one point when light passes through the lens surface 24S in comparison with light passing through a lens surface that completely lacks a recessed hole.

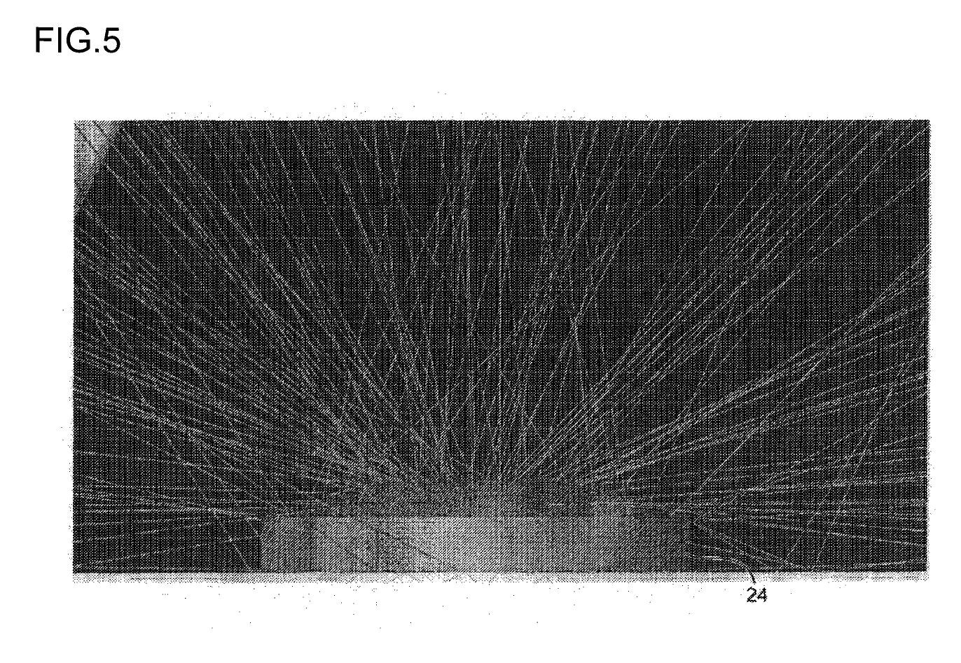

In other words, the curved surface of the lens surface 24S encircling the recessed hole 24D has a greater curvature than the curved surface of a lens that lacks a recessed hole, and light from the LED 22 therefore diffuses without concentrating in the vicinity directly above the recessed hole 24D (the lens 24 can therefore be referred to as a diffusion lens). As a result, light from the LED 22 covered by the recessed hole 24D is directed in a radiating direction, which centers on the recessed hole 24D, by the lens surface 24S encircling the recessed hole 24D (refer to the image in FIG. 5).

The material of the lens 24 is not particularly limited and may, for example, be an acrylic resin (an acrylic resin having a refractive index nd of 1.49 to 1.50 can be given as an example). The attachment method of the lens 24 and the mounting substrate 21 is also not particularly limited. For example, the legs 24F protruding so as to provide separation from the lens surface 24S are formed on the outside edge 24E of the lens 24, and the mounting surface 21U and the legs 24F may be bonded to each other by, for example, a bonding agent (not shown) (leg apertures 11HF for allowing the legs 24F to pass through are formed in the built-in reflective sheet 11 interposed between the lens 24 and the mounting substrate 21), as shown in FIG. 1.

The LED modules MJ are laid out across the bottom surface 41B of the backlight chassis 41 using, for example, a box-shaped member, whereby the plurality of LED modules MJ is accommodated as shown in FIG. 16. The bottom surface 41B of the backlight chassis 41 and the mounting substrates 21 of the LED modules MJ are connected using rivets (not shown).

Support pins for supporting the diffuser 43, the prism sheet 44, and the microlens sheet 45 may be attached to the bottom surface 41B of the backlight chassis 41 (the backlight chassis 41, as well as the support pins, may support, in sequence, the diffuser 43, the prism sheet 44, and the microlens sheet 45 stacked in layers at the top of the side wall).

The large reflective sheet (second reflective sheet) 42 is an optical sheet having the reflective surface 42U, and is used to cover the matrically disposed plurality of LED modules MJ in a manner facing the rear surface of the reflective surface 42U. However, the large reflective sheet 42 includes the through-holes 42H aligned with the position of the lenses 24 of the LED modules MJ, and the lenses 24 are exposed via the reflective surface 42U (there may also be apertures for exposing the aforementioned rivets and support pins).

Even if part of the light that is output from the lenses 24 is then transmitted toward the bottom surface 41B of the backlight chassis 41, the light is reflected by the reflective surface 42U of the large reflective sheet 42, and transmitted so as to be separated from the bottom surface 41B thereof. Accordingly, the presence of the large reflective sheet 42 allows the light from the LEDs 22 to be directed without any loss to the diffuser 43 facing the reflective surface 42U.

The diffuser 43 is an optical sheet overlapping the large reflective sheet 42, and is used to diffuse light emitted from the LED modules MJ and light reflected from the large reflective sheet 42. Specifically, the diffuser 43 diffuses planar light formed by the plurality of LED modules MJ, and spreads the light over the entire liquid crystal display panel 59. The diffuser 43 preferably has a permeability of 52 to 60%. This is because such a diffuser 43 can diffuse light while allowing adequate permeation of light to reduce irregularities in the quantity of light.

The prism sheet 44 is an optical sheet overlapping the diffuser 43. In the prism sheet 44, for example, triangular prisms that extend in one direction (linearly) are lined up within the plane of the sheet in a direction that intersects the extension direction of the prisms. The prism sheet 44 thereby creates a bias in the radiating characteristics of the light from the diffuser 43. The prisms may extend along the Y direction, in which a small number of LEDs 22 is disposed, and may be lined up along the X direction, in which a large number of LEDs 22 is disposed.

The microlens sheet 45 is an optical sheet overlapping the prism sheet 44. The microlens sheet 45 disperses, inside the sheet, particulate in which light was refractively scattered. The microlens 45 thereby reduces the contrast (irregularities in the quantity of light) without concentrating light from the prism sheet 44 in a localized manner.

In such a backlight unit 49, planar light formed by the plurality of LED modules MJ is made to pass through a plurality of optical sheets 43 to 45, and is supplied to the liquid crystal display panel 59. The liquid crystal display panel 59, which does not emit light, thereby receives light (backlight light) from the backlight unit 49 to improve display function.

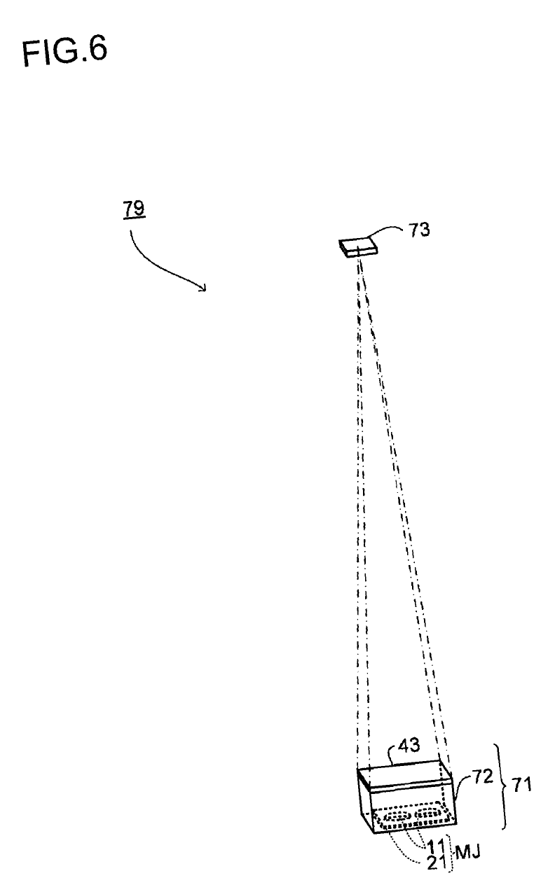

The illuminance of light emitted from the lenses 24 in the LED modules MJ will now be described. FIG. 6 is a schematic view of a simulation device 79. The simulation device 79 includes an experimental unit 71 and a photo camera 73.

The experimental unit 71 is a reflective surface having a reflectance on the bottom surface of about 97%, and a reflective surface having a reflectance on an inner wall of substantially 100%. An LED module MJ having two lenses 24 is also installed in a box 72 that includes an aperture. A diffuser 43 is disposed in the aperture of the box 72 in the experimental unit 71, whereby light from the LED module MJ permeates the diffuser 43.

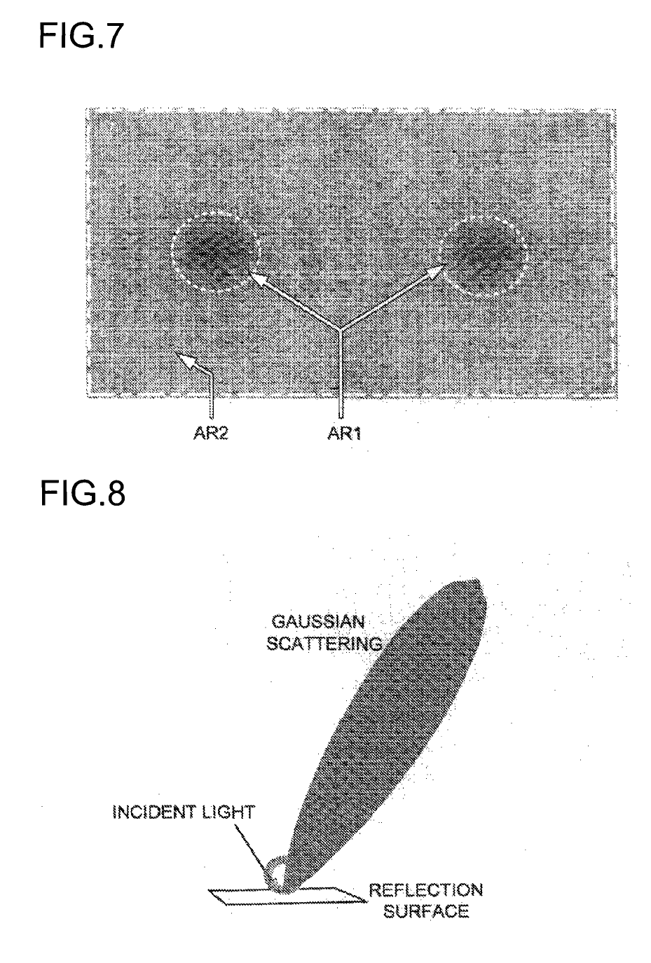

The photo camera 73 photographs the diffuser 43, whereby the illuminance on the surface of the diffuser 43 is measured. That is, an image is photographed in which the illuminance level can be distinguished in each area in two dimensions, as shown in FIG. 7.

An image showing two circles (circles of dotted lines) is obtained by the photo camera 73, as shown in FIG. 7. The image of the circles represents light that has passed through the lens 24. The circular lines show the boundary lines of the illuminance range, which is the contrast. The image in FIG. 7 therefore includes an area AR1 encircled by only the dotted line, and an area (area encircled by the dotted/dashed-line frame that excludes the area demarcated by the dotted line) AR2 that includes everything else. The illuminance relationship is LN1>LN2, where the illuminance (lumen) of the areas AR1 and AR2 is LN1 and LN2, respectively (the relations LN1>88% and 75%<LN2≦88% will be obtained if LN1 and LN2 are normalized to maximum illuminance).

The LED module MJ showing an illuminance image such as the one shown in FIG. 7 includes LEDs 22, a mounting substrate 21 for mounting the LEDs 22, lenses 24 in which light from the LEDs 22 is output from a lens surface 24S, and a built-in reflective sheet 11 interposed between a back surface 24B opposite to the lens surface 24S and the mounting substrate 21 and provided with a built-in reflective surface 11U facing the back surface 24B of the lens 24.

In such an LED module MJ, Gaussian scattering such as that shown in FIG. 8 occurs on the built-in reflective surface 11U of the built-in reflective sheet 11. In cases in which such Gaussian scattering occurs, the light reflected by the back surface 24B of the lens 24 is further reflected by the built-in reflective surface 11U. The light then reaches the back surface 24B of the lens 24 and is incident on the inside of the lens 24.

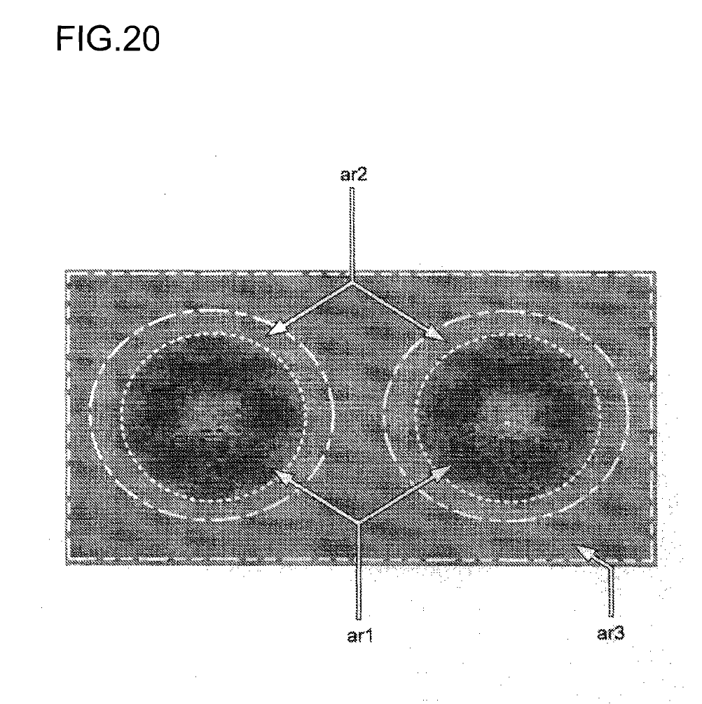

Accordingly, in the LED module MJ, situations do not arise in which the light reflected by the back surface 24B of the lens 24 is absorbed by, for example, the mounting surface 21U, or is reflected by the mounting surface 21U and fails to become incident on the back surface 24B of the lens 24. In other words, the light from the LED 22 is output via the lens 24 without loss. As a result, the area AR1 showing the illuminance LN1 increases, and the illuminance of the entire illuminance range based on the LED module MJ rises (FIG. 20 is given as an example of reduced illuminance of the entire illuminance range), as shown in FIG. 7. Therefore, irregularities in the quantity of light rarely occur in the light emitted from the LED module MJ.

The illuminance of the backlight unit 49 in which such LED modules MJ are installed also increases, and irregularities in the quantity of light rarely occur in the light from the backlight unit 49. Moreover, the image quality of the liquid crystal display device 69 in which such a backlight unit 49 is installed also improves (in short, the liquid crystal display device 69 can display images that are free from irregularities in the quantity of light).

The reflection produced on the built-in reflective surface 11U of the built-in reflective sheet 11 can be considered something other than Gaussian scattering. For example, light may be caused to undergo Lambert scattering by subjecting the built-in reflective surface 11U to surface texturing (in short, the built-in reflective surface 11U may be a perfect reflecting diffuser).

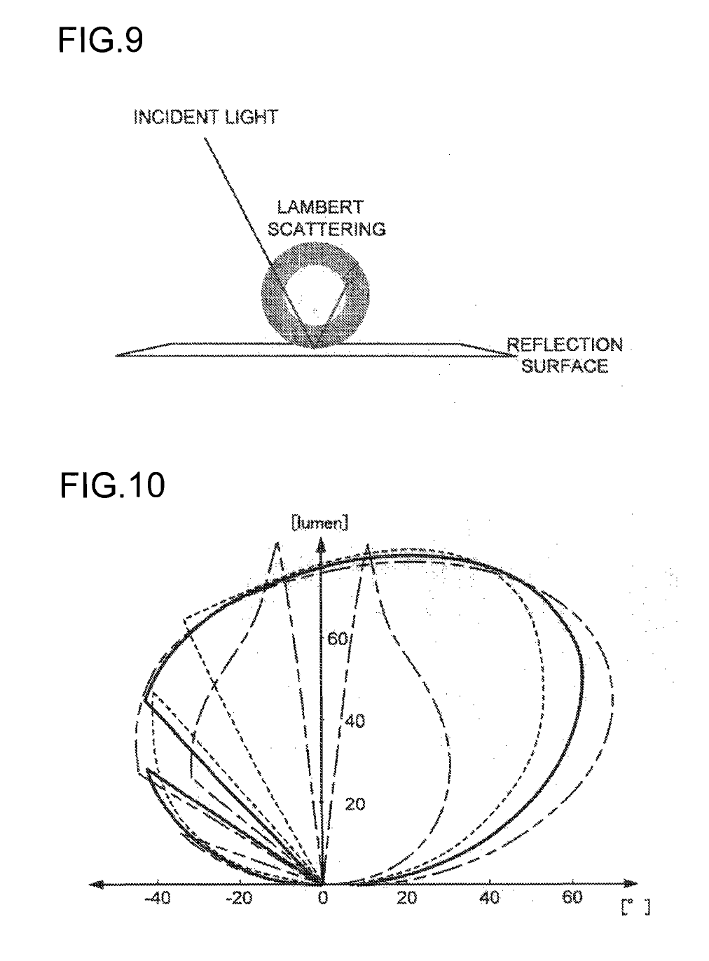

Lambert scattering is different from that in FIG. 8, which is an explanatory view of Gaussian scattering, and involves reflection of light only in a particular direction, as shown in the explanatory view in FIG. 9. This is apparent in FIG. 10, which shows the measurement results of a light distribution measurement system (Goniophotometer GC5000, Nippon Denshoku Industries).

FIG. 10 is a polar graph, where the horizontal axis is the angle (unit of measurement: degrees) and the size of the normal direction (vertical axis) is the illuminance (unit of measurement: lumen). The shape encircled by the graph line shows the reflective state of light reflected at the point of incidence. It is therefore understood from FIG. 10 that light is reflected (scattered) in various directions in the case of Lambert scattering.

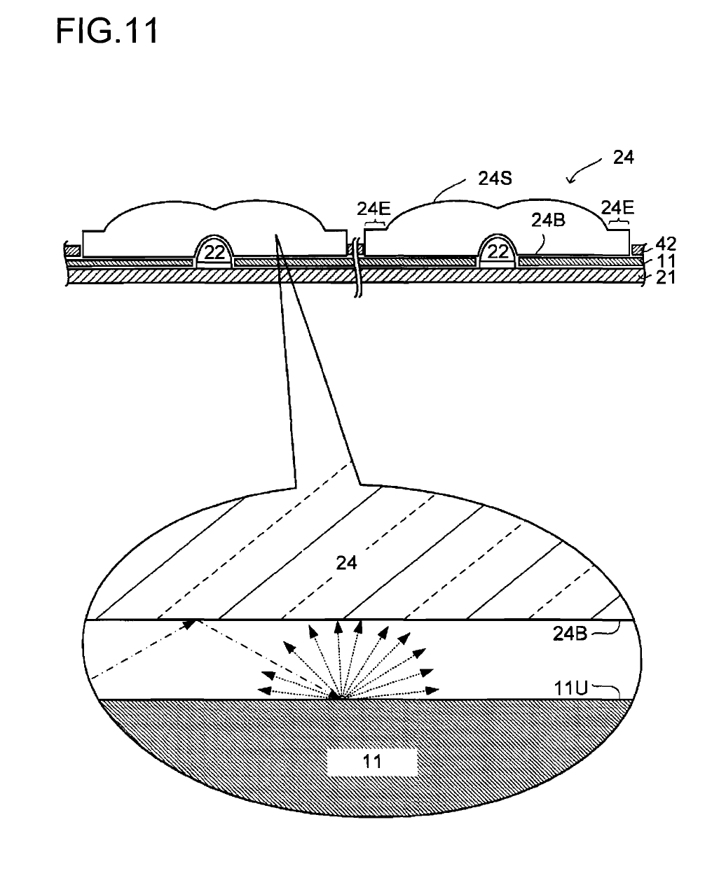

In cases in which such Lambert scattering is produced by the built-in reflective surface 11U of the built-in reflective sheet 11, a phenomenon occurs such as shown in the optical path diagram in FIG. 11. Specifically, the light (dotted/dashed arrow) that reached the built-in reflective surface 11U is diffused, and most of the diffused light (refer to the dotted arrows) is incident on the back surface 24B of the lens 24 and is allowed to enter the lens 24.

In such a case, loss of light (reduction in the percentage of light from the LED 22 that is incident on the lens 24) is rare, which is different than with Gaussian scattering. This is because in the case of Gaussian scattering, the light reflected by the built-in reflective surface 11U is transmitted in a particular direction, and often does not reach the back surface 24B of the lens 24, but in the case of Lambert scattering, the light reflected by the built-in reflective surface 11U is transmitted in various directions, and the quantity of light that does not reach the back surface 24B of the lens 24 is therefore minute.

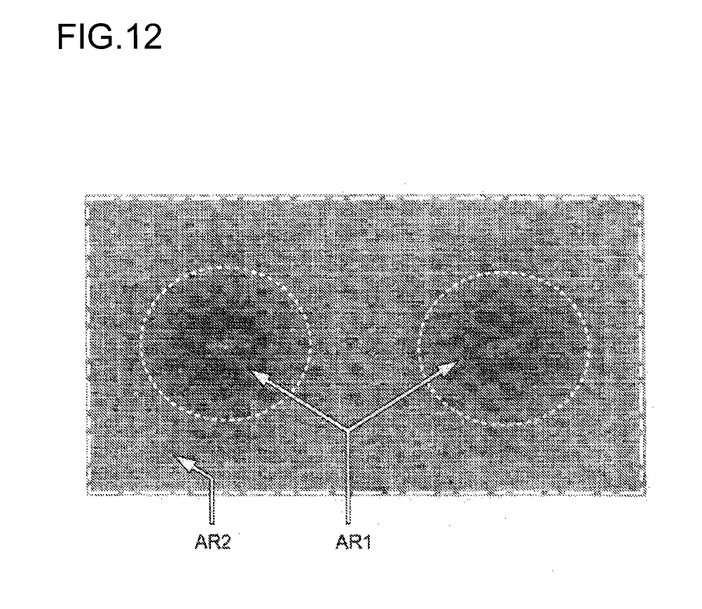

As a result, the area AR1 showing the illuminance LN1 is larger and the illuminance of the entire illuminance range based on the LED module MJ is even higher in the illuminance image of this LED module MJ, in which Lambert scattering is induced in the built-in reflective surface 11U as shown in FIG. 12, than in the illuminance image of FIG. 7.

Based on the above, in cases in which the illuminance of the entire illuminance range based on the LED module MJ increases and becomes substantially uniform, as shown in FIGS. 12 and 7, the illuminance of the backlight light from the backlight unit 49 also increases and becomes uniform as a result. Light from the backlight unit therefore has no irregularities in the quantity of light.

In addition, a smaller number of optical sheets for preventing irregularities in the quantity of light contained in the backlight unit 49 may be used (in short, the cost of the backlight unit 49 is lessened and the backlight unit 49 is made thinner) because of the suppressed irregularities in the quantity of light that is output from the LED modules MJ.

The built-in reflective surface 11U in which Lambert scattering is induced includes a grain pattern, but the method for forming the grain pattern (surface texturing) is not particularly limited. The grain pattern can be formed by, for example, masking, roll transferring, extruding, or another of various methods.

Light-scattering beads (scatter particles) for scattering light may also be coated on the built-in reflective surface 11U as a method other than surface texturing. In other words, a coating surface formed by coating the built-in reflective surface 11U with beads may be used as long as Lambert scattering occurs. The surface roughness (Ra) of the built-in reflective surface 11U thus roughened is 400 nm or greater.

A rough surface (Lambert scattering surface) formed by surface texturing or the like may be formed on the back surface 24B of the lens 24. In such a case, light incident on the back surface 24B of the lens 24 is directly scattered from the LED 22.

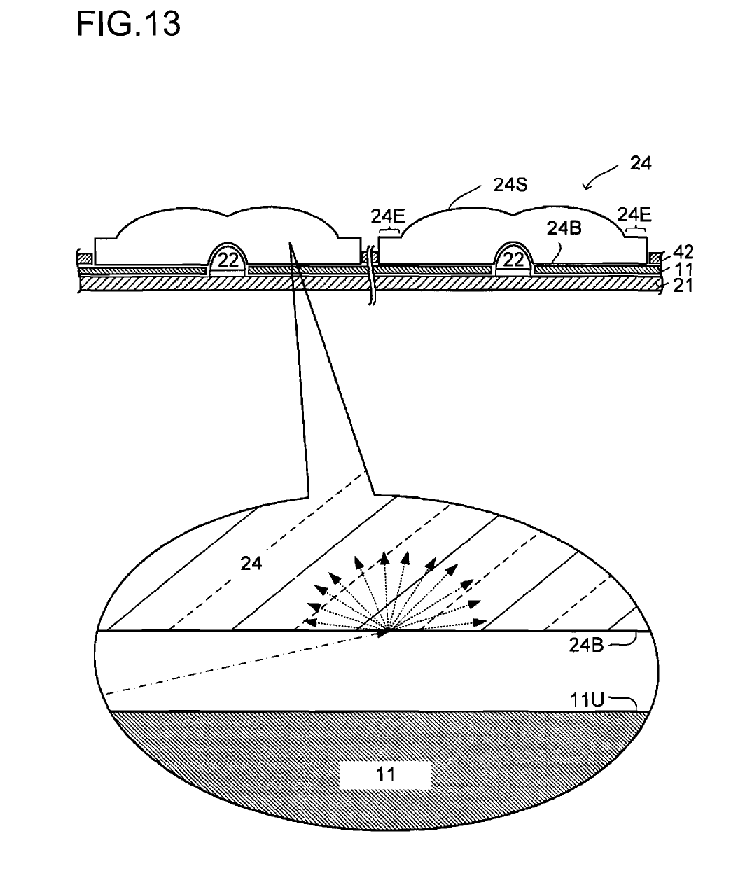

Part of the light scattered in various directions is therefore incident on the built-in reflective surface 11U of the built-in reflective sheet 11. Even if this occurs, most of the light is returned to the back surface 24B of the lens 24 and is allowed to enter the lens 24 (in this case, the built-in reflective surface 11U may be a Lambert scattering surface or a Gaussian scattering surface). Another part of the light diffused in various directions is also transmitted as shown in the optical path diagram in FIG. 13. Specifically, part of the light that reached the back surface 24B of the lens 24 (dotted/dashed arrow) is allowed to enter the lens 24 unchanged while being scattered.

As a result, light from the LED 22 is securely output via the lens 24 without loss, and the illuminance of the entire illuminance range based on the LED module MJ is further increased. Such a scattered state is confirmed as a comparatively good result in a verification performed using, for example, the optical analysis software SPEOS of OPTIS Asia & Pacific.

### Other Embodiments

The present invention is not limited to the above-described embodiment, and various modifications may be possible without departing from the scope of the present invention.

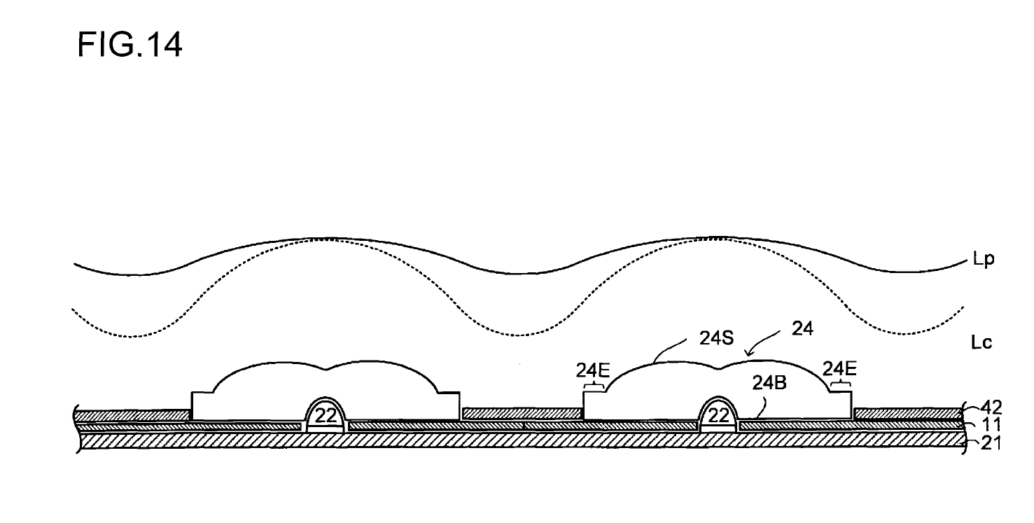

For example, the large reflective sheet 42 preferably has a reflectance of 97% or greater. In such a case, the brightness in the vicinity directly above the space between the lenses 24 is not excessively low in comparison with the brightness in the vicinity directly above either of the lenses 24, as shown in FIG. 14, in which the position of the lenses 24 and the brightness curves Lp and Lc are shown together.

When described in detail, the brightness curve Lp shows the brightness of light from the LED module MJ covered by the large reflective sheet 42 having a reflectance of 97%. The brightness curve Lc shows the brightness of light from the LED module MJ in a case in which the module is not covered by the large reflective sheet 42 (the maximum brightness of the brightness curves Lp and Lc is substantially the same value). As can be seen from the brightness curve Lc and the brightness curve Lp in FIG. 14, the difference between the brightness in the vicinity directly above any of the lenses 24 and the brightness in the vicinity directly above the space between the two lenses 24 on the brightness curve Lp is therefore less than the difference between the brightness in the vicinity directly above any of the lenses 24 and the brightness in the vicinity directly above the space between the two lenses 24 on the brightness curve Lc.

The size of such a difference in brightness shows the presence or absence of irregularities in the quantity of light from the backlight unit 49 (in short, irregularities in the quantity of light occur when the brightness difference is large). Irregularities in the quantity of light are present in light from the backlight unit 49 provided with LED modules MJ not covered by the large reflective sheet 42, but there are no irregularities in the quantity of light from the backlight unit 49 provided with LED modules MJ covered by the large reflective sheet 42 having a reflectance of 97%. In other words, it can be said that the large reflective sheet 42 having a reflectance of 97% is preferably installed in the backlight unit 49.

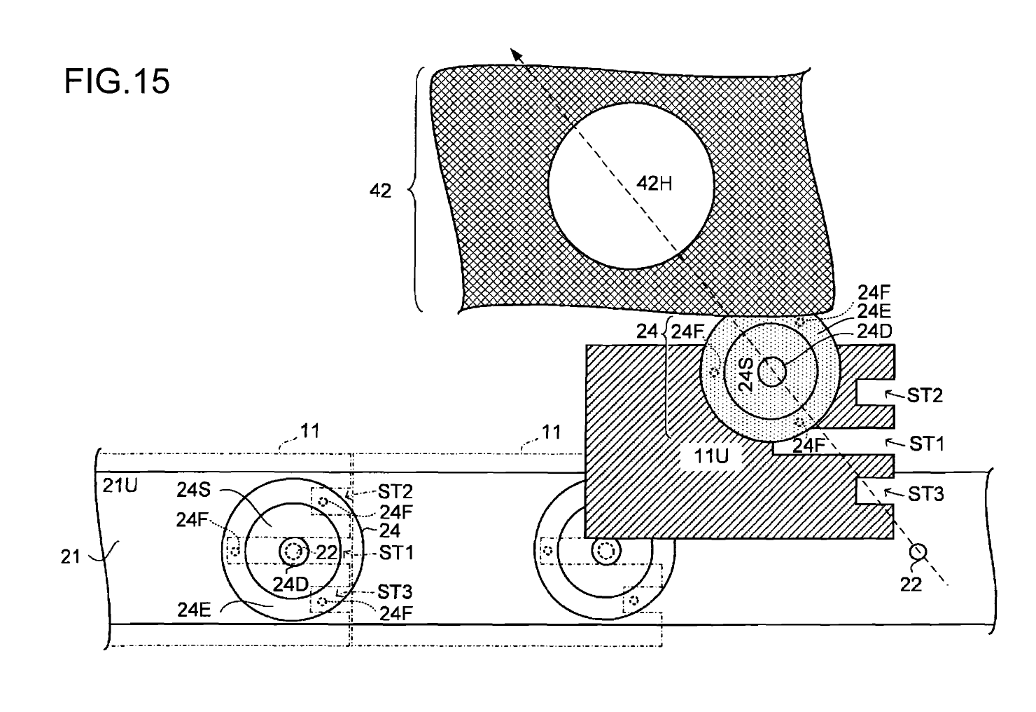

The shape (outer shape) of the built-in reflective sheet 11 is not limited to a circular shape such as that shown in FIG. 3. For example, the built-in reflective sheet 11 may have a rectangular outer shape. The outer shape of the built-in reflective sheet 11 may be made substantially rectangular, and may include slits ST for avoiding contact between the LED 22 and the legs 24F of the lens, as shown in FIG. 15.

When described in detail, the three notches ST are inserted on one side of the rectangular outer shape in the built-in reflective sheet 11 shown in FIG. 15. The notches are designed so that the LED 22 and one leg 24F of the lens 24 are placed in the middle notch ST1 of the three notches lined up in a row, and one leg 24F is placed in each of the remaining two notches ST2 and ST3.

With such a built-in reflective sheet 11, the built-in reflective sheet 11 is placed between the mounting surface 21U and the back surface 24B of the lenses 24 by moving the built-in reflective sheet 11 along the mounting surface 21U after the lenses 24 are attached to the mounting substrate 21. The LED modules MJ can therefore be assembled with a greater degree of freedom. In addition, the built-in reflective sheet 11 can be removed from the temporarily completed LED modules MJ (reworking is possible).

A light-guiding plate is usually omitted in a direct-lighting backlight unit, and light from the LEDs is directly incident on the optical sheet (diffuser or the like). However, irregularities in the quantity of light occur in a case in which the light is output via the optical sheet if the light does not spread to some extent before reaching the optical sheet. Accordingly, a greater distance is preferably established from the LEDs to the diffuser.

However, in cases in which a lens 24 that includes a lens surface 24S having a recessed hole 24D covers each of the LEDs 22, light from the LEDs 22 is fully diffused before reaching the diffuser 43, and there are therefore no irregularities in the quantity of backlight light from the backlight unit 49. In addition, the distance from the LEDs 22 to the diffuser 43 may be comparatively small (in short, a comparatively thin backlight unit 49 is obtained and the liquid crystal display panel 69 in which the backlight unit 49 is installed can also be made thin with ease).

However, many LEDs 22 are installed in the backlight unit 49 provided with the LED modules MJ shown in FIG. 16, and each of the LEDs 22 is covered by a lens 24. The drive heat of the LEDs 22 is therefore easily trapped in narrow spaces such as the accommodating depressions DH of the lenses 24 (consequently, the LEDs 22 cannot maintain a comparatively high optical intensity due to the drive heat of the LEDs).

In view of this, the LED modules MJ are preferably attached to the backlight chassis 41 formed of a material having high heat dissipation, for example, a metal. In such a case, another heat dissipation member is unnecessary between, for example, the mounting substrate 21 and the bottom surface 41B of the backlight chassis 41.

The drive heat of the LEDs 22 easily escapes to the outside without being trapped in narrow spaces such as the accommodating depressions DH of the lenses 24 when a gap is created between the back surface 24B of the lenses 24 and the mounting surface 21U by the legs 24F of the lenses 24 such as that shown in FIG. 1. This makes it possible to complete a backlight unit 49 in which the light intensity can be maintained for a long period of time with a decreased cost.

The LEDs 22, which are light-emitting elements, are described above as the light source, but this is not the only option. For example, light-emitting elements formed of a self-luminous material such as an organic EL (electro-luminescence) or non-organic EL material may also be used.

### LIST OF REFERENCE SIGNS

11 Built-in reflective sheet (first reflective sheet)
11U Built-in reflective surface (reflective surface)
11F Leg
11HL LED aperture
11HF Leg aperture
ST Notch
24 Lens
24E Outer edge of lens
24S Lens surface
24B Back surface of lens surface
24D Recessed hole
21 Mounting substrate
21U Mounting surface
22 LED (light-emitting element, light source)
23 Built-in reflective sheet
MJ LED module (light-emitting module)
41 Backlight chassis
42 Large reflective sheet (second reflective sheet)
43 Diffuser
44 Prism sheet
45 Microlens sheet
49 Backlight unit (illumination device)
59 Liquid crystal display panel (display panel)
69 Liquid crystal display device (display device)
71 Experimental unit
73 Photo camera
79 Simulation device
89 Liquid crystal television (television receiver)

1. A light-emitting module comprising:
a light-emitting element;
a mounting substrate for mounting the light-emitting element;
a lens in which light from the light-emitting element is output from a lens surface; and
a first reflective sheet interposed between a back surface of the lens surface and the mounting substrate, and provided with a reflective surface facing the back surface of the lens surface.

2. The light-emitting module of claim 1, wherein the reflective surface of the first reflective sheet is a Lambert scattering surface.

3. The light-emitting module of claim 1, wherein the back surface of the lens surface is a Lambert scattering surface.

4. The light-emitting module of claim 2, wherein the Lambert scattering surface is a textured surface or a coating surface coated with scattering particles.

5. The light-emitting module of claim 2, wherein the surface roughness (Ra) of the Lambert scattering surface is 400 nm or greater.

6. The light-emitting module of claim 1, wherein the lens is a diffusion lens.

7. An illumination device comprising the light-emitting module of claim 1.

8. The illumination device of claim 7, wherein a second reflective sheet is disposed between the lenses in a pair, and the reflectance of the second reflective sheet is 97% or greater.

9. A display device comprising: the illumination device of claim 7; and
a display panel for receiving light from the illumination device.

10. The display device of claim 9, wherein the display panel is a liquid crystal display panel.

11. A television receiver wherein the display device of claim 9 is installed.
